(19) United States
(12) Patent Application Publication
(10) Pub. No.: US 2003/0227402 A1
(43) Pub. Date: Dec. 11, 2003

(54) Method and apparatus for reducing systematic errors in a current steering digital-to-analog converter

(75) Inventors: Janusz Starzyk, Athens, OH (US); Tom Senko, Plainsboro, NJ (US); Russell Mohn, Plainsboro, NJ (US)

Correspondence Address: MOSER, PATTERSON & SHERIDAN, LLP, /SARNOFF CORPORATION, 595 SHREWSBURY AVENUE, SUITE 100, SHREWSBURY, NJ, 07702, US

(73) Assignee: Sarnoff Corporation

(21) Appl. No.: 10/395,690

(22) Filed: Mar. 24, 2003

Related U.S. Application Data
(60) Provisional application No. 60/366,951, filed on Mar. 22, 2002.

(51) Int. Cl. H03M 1/66

(52) U.S. Cl. 341/144

(57) ABSTRACT

Method and apparatus for reducing systematic errors in a current steering digital-to-analog converter. The present invention is an efficient method of determining a switching order such that given a known distribution of mismatch errors, the cumulated error is minimized at each DAC code.

This application claims the benefit of U.S. Provisional Application No. 60/366,951 filed on Mar. 22, 2002, which is herein incorporated by reference.

The invention relates generally to digital-to-analog devices (“DAC”) and, more specifically, to a method and apparatus for reducing systematic errors in current steering DACs.

### BACKGROUND OF THE INVENTION

Designs for modem communication hardware, e.g. broadband modems for new communication standards and wireless communication systems, require high performance at a low cost. Integration of digital and analog components on a single chip is a recommended system level solution and this makes design of mixed-signal macrocells, e.g. a digital-to-analog converter (DAC) even more challenging than design of stand alone components. Chip size is of critical importance due to high cost and low yield of the manufacturing process for advanced system on a chip (SOC) solutions. Since broadband communications IC's require high-speed and high-accuracy DACs and analog-to-digital converters (ADCs), current-steering DACs are often used. Current-steering DACs are based on an array of matched current cells organized in unary encoded or binary weighted elements that are steered to the DAC output depending on the digital input code.

Typically, current steering DACs are designed using a segmented architecture in which input bits are divided into two groups with lower significance bits switching the binary coded current sources and higher significance bits switching thermometer coded unary current sources. Both binary and unary sources use matched transistors where the transistor area is designed using statistical process parameters, e.g. S_{β} and A_{β} (a process parameter or technology constant), to attain a desired accuracy.

However, since any two DACs that are processed in the same technology do not necessarily have the same specifications due to technological variations, it is important to know the relationship that exists between the circuit specifications and the matching properties of the fabrication technology. For a current-steering DAC, the integral nonlinearity (INL) is mainly determined by the mismatch of the current sources. In addition to INL, differential nonlinearity (DNL) is also greatly influenced by the choice of DAC architecture.

In other words, to attain high performance in a current steering DAC, it is important that the individual current sources composing the DAC array will match closely and within the design goals. A common method of increasing matching between current sources is to increase the area of the MOS transistors composing the current sources. Another method is to keep the individual current sources physically close to one another in order to suppress any systematic errors that may arise due to their placement in the IC layout and the subsequent manifestation of matching errors from process or temperature gradients.

Unfortunately the above two methods are in conflict. One cannot simply increase the area of the current sources, thereby making them arbitrarily large in the hope of increasing the matching. As the current sources get larger so does the size of the entire DAC array. The resulting increase in spacing between sources results in increasing mismatch due to systematic errors.

Therefore, there is a need for a method and architecture for a DAC that will minimize systemic errors and allow a designer to further minimize the size and/or cost of a DAC.

### SUMMARY OF INVENTION

The present invention is a method and apparatus for reducing systematic errors in a current steering digital-to-analog converter. The invention advantageously provides a method for generating a switching permutation to minimize the maximum value of the cumulative sum of mismatch errors in a natural order.

Specifically, the present invention presumes that systematic errors are known for all current sources and are represented by a numerical sequence of their current mismatch. This sequence has its natural order, where all the current sources will be represented by their natural order indexes. The present invention sets a proper or new order to each index in this numeral sequence, thereby effectively creating a permutation of the natural order. Thus, given a known distribution of mismatch errors, the present invention generates a new ordered sequence such that the cumulated error is minimized at each DAC code. The present method can be applied to an array of current sources, voltage sources, and passive elements such as resistors, capacitors and the like.

After the ordered sequence is generated, the present invention also discloses a method for mapping a latch array to the current source array. One advantage of this mapping method is that it is able to employ the ordered sequence as discussed above to map a latch array having a fixed order to the current source array.

### BRIEF DESCRIPTION OF THE DRAWINGS

The teachings of the present invention can be readily understood by considering the following detailed description in conjunction with the accompanying drawings, in which:

FIG. 1 depicts a portion of a typical current-steering digital-to-analog converter;

FIG. 2 depicts a graph of the distribution of the random mismatch errors plotted against the order numbers for a 16 by 16 array of unit current sources;

FIG. 3 depicts a switching order or permutation such that given a known distribution of mismatch errors, the cumulated error can be minimized at each DAC code;

FIG. 4 depicts a flowchart of a method for generating a switching permutation to minimize the maximum value of the cumulative sum of mismatched errors;

FIG. 5 depicts a graph comparing cumulative sum of mismatched errors of a natural order versus cumulative sum of mismatched errors of a permutation of the natural order;

FIG. 6 depicts an order imposed upon a latch array;

FIG. 7 depicts a latch array and current source array of a DAC;

FIG. 8 depicts a portion of a current source array of the present invention;

FIG. 9 depicts a flowchart of a method for placing vias to accomplish the mapping of all latches to the current sources;

FIG. 10 illustrates a quadrant of the current source array; and

FIG. 11 illustrates a current source within the quadrant.

To facilitate understanding, identical reference numerals have been used, where possible, to designate identical elements that are common to the figures.

### DETAILED DESCRIPTION OF THE INVENTION

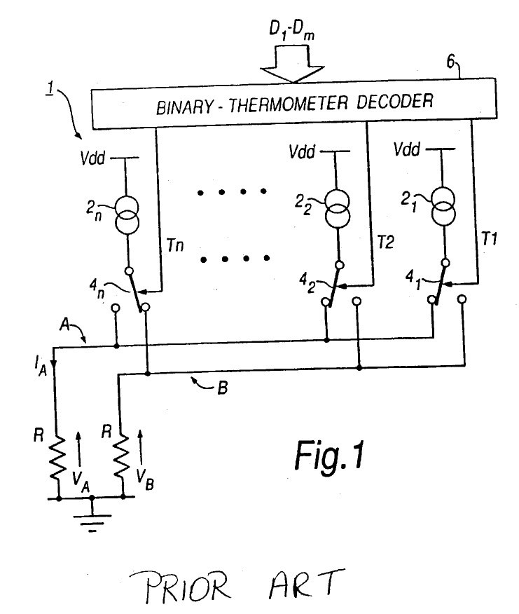

FIG. 1 of the accompanying drawings shows parts of a conventional digital-to-analog converter (DAC) of the so-called “current-steering” type. The DAC 1 is designed to convert an m-bit digital input word (D₁-Dₘ) into a corresponding analog output signal.

The DAC 1 includes a plurality (n) of identical current sources 2₁ to 2ₙ, where n=2^{m}−1. Each current source 2 passes a substantially constant current I. The DAC 1 further includes a plurality of differential switching circuits 4₁ to 4ₙ corresponding respectively to the n current sources 2₁ to 2ₙ. Each differential switching circuit 4 is connected to its corresponding current source 2 and switches the current I produced by the current source either to a first terminal, connected to a first connection line A of the converter, or a second terminal connected to a second connection line B of the converter.

Each differential switching circuit 4 receives one of a plurality of thermometer-coded control signals T1 to Tn and selects either its first terminal or its second terminal in accordance with the value of the signal concerned. A first output current I_{A} of the DAC 1 is the sum of the respective currents delivered to the differential-switching-circuit first terminals, and a second output current I_{B} of the DAC 1 is the sum of the respective currents delivered to the differential-switching-circuit second terminals.

The analog output signal is the voltage difference V_{A}-V_{B} between a voltage V_{A} produced by sinking the first output current I_{A} of the DAC 1 into a resistance R and a voltage V_{B} produced by sinking the second output current I_{B} of the converter into another resistance R.

The thermometer-coded signals T1 to Tn are derived from the binary input word D₁-Dₘ by a binary-thermometer decoder 6. When a binary input word D₁-Dₘ has the lowest value all thermometer-coded signals T1-Tn are such that each of the differential switching circuits 4₁ to 4ₙ selects its second terminal so that all of the current sources 2₁ to 2ₙ are connected to the second connection is line B. In this state, V_{A}=0 and V_{B}=nIR. The analog output signal V_{A}-V_{B}=−nIR.

As the binary input word D₁-Dₘ increases progressively in value, the thermometer-coded signals T1 to Tn produced by the decoder 6 are such that more of the differential switching circuits select their respective first terminals (starting from the differential switching circuit 4₁) without any differential switching circuit that has already selected its first terminal switching back to its second terminal. When the binary input word D₁-Dₘ has the value i, the first i differential switching circuits 4₁ to 4ᵢ select their respective first terminals, whereas the remaining n-i differential switching circuits 4ᵢ₊₁ to 4ₙ select their respective second terminals. The analog output signal V_{A}-V_{B} is equal to (2i−n)IR.

Since the typical DAC array or at least the most significant bits of a high resolution DAC are thermometer decoded, there is an opportunity to suppress mismatch errors by arranging for the cumulative sum of these errors to cancel for each code of the DAC. Thermometer coding is a method where the DAC output rises with increasing code values in a linear fashion, much like a thermometer. This means that the kth code will send an output from the DAC which is the sum of k number of unit current sources. If at this kth code, a set of k current sources whose cumulative mismatch error is zero or at least minimum can be obtained, then the design goals can be met at this kth code. Thus, by ensuring that at all codes for the DAC the cumulative sum of the unit source errors is minimum, then the entire DAC will meet the design goals.

In other words, if the systematic errors, or random errors for that matter can be obtained for the DAC array, the present invention will generate a switching order such that the cumulative sum of the mismatch errors at any code will be minimized. The method for arranging this switching order is described below.

In describing the present invention, a 16 by 16 array of unit current sources which are thermometer decoded will be used as an example. The current sources are arranged with 16 columns along the Y axis and 16 rows along the X axis. Such an array could be implemented as the most significant bits of a high resolution DAC.

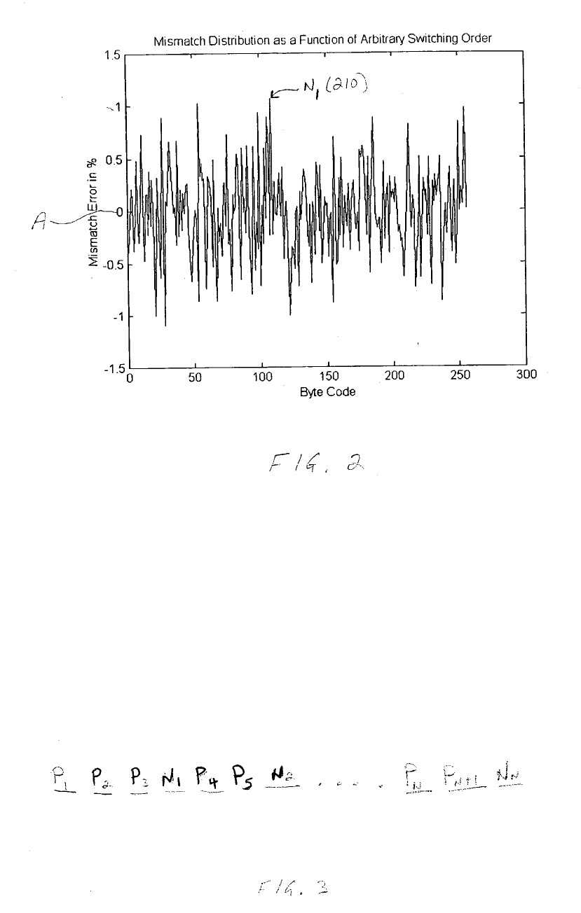

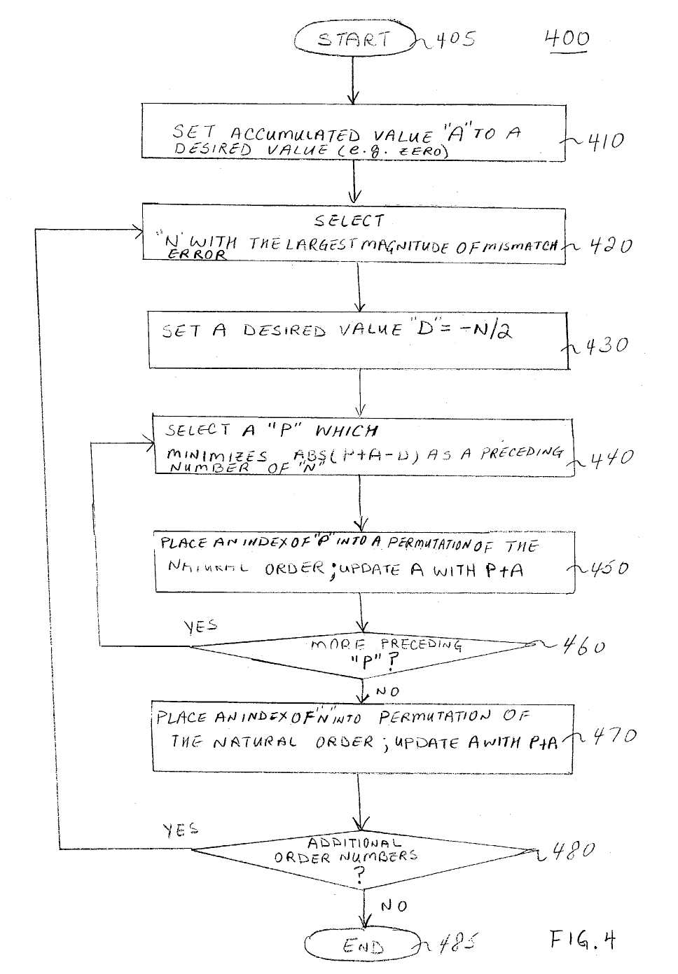

If an arbitrary order to this array is now assigned such that each unit current source is assigned an order number (or byte code) from 0 to 255, then the distribution of the random mismatch errors (y-axis) can be plotted against the order numbers (x-axis). This arbitrary order of the array is referred to as its natural order. FIG. 2 illustrates such a graph. Systematic errors in a steerable DAC can be significantly reduced if thermometer-controlled transistors are switched in a pseudo random sequence designed to minimize the cumulative sum of mismatched errors. FIG. 4 depicts a flowchart of a method 400 that generates a switching permutation to minimize the maximum value of this cumulative sum of mismatched errors. The reader is encouraged to refer to FIGS. 2-4 collectively to understand the present invention.

Method 400 presumes that systematic errors are known for all current sources and are represented by a numerical sequence of their current mismatch as illustrated in FIG. 2. This sequence has its natural order, where all the current sources will be represented by their natural order indexes. The permutation method 400 sets a proper or new order to each number in this numeral sequence, thereby effectively creating a permutation of the natural order.

Method 400 starts in step 405 and proceeds to step 410. Method 400 sets a desired accumulated current mismatch error “A” to a desired value, e.g., zero. Namely, it is desirable to limit the accumulated mismatch error as low as possible. However, since it is not necessary that the accumulated mismatch error be exactly equal to zero, the desired value A can be set to other values (e.g., between −1 to 1) as long as a maximum accumulated mismatch error is not exceeded in accordance with a particular implementation requirement. Thus, in step 410, method 400 sets a desired accumulated value of the accumulated mismatch error “A” to zero.

In step 420, a number “N” corresponding to a mismatch error with the largest magnitude is selected. This number “N” has associated with it an index (DAC code or byte code, e.g., 210 of FIG. 2) from the natural order. It should be noted that the largest magnitude can be positive or negative. Additionally, although the present invention describes the selection of a mismatch error with the largest magnitude as a starting point, those skilled in the art will realize that it is possible to practice the present invention by selecting the second largest magnitude (or third largest and so on) before selecting the largest magnitude. In essence, one should start with a number N that has a relatively large mismatch error magnitude as compared to other numbers in the natural order. Namely, such slight variations in the starting point still fall within the scope of the present invention.

In step 430, a desired value D is selected, e.g., −N/2. In other words, the magnitude of D is selected to be one half of the magnitude of the selected number N. For the same reason as stated above, D can be selected to be at other values, e.g., between N/3 and 2N/3.

In step 440, method 400 selects a number P (e.g., P₁) that minimizes the abs(P+A−D), where an index of P will then be set into an order that precedes an index of N. P represents one of the mismatch error values other than the current mismatch error N having the largest magnitude. The value of P selected should reduce the distance between A and D such that the abs(P+A−D) is less than the abs(A−D) and either A and D have opposite sign or that absolute value of A is less than the absolute value of D.

It should be noted that A and D have opposite signs and that abs(A) is less than abs(D). Thus, those skilled in the art will realize that the present usage of sign is relative to the applied operation, i.e., D can be selected to be N/2 and that P can be selected to minimize abs(P−A+D) and so on.

After appropriate selection of P, the method 400 at step 450 places an index representative of P in a new order or in a permutation of the natural order (with N as the last value in the order) and removes P from consideration. Additionally, A is updated with P+A.

In step 460, the method 400 queries whether there are other mismatch error values Pₙ that will minimize abs(P+A−D) as preceding numbers. If the query is positively answered, then the method 400 proceeds back to step 440 for selection of another value P (e.g., P₂) that minimizes the value of the abs(P₂+A−D), provided A was updated in step 450 above. The iteration of steps 440-460 is repeated until no more such numbers can be found. If the query is negatively answered, then the method 400 proceeds to step 470, where N is placed within the new order and is removed from consideration. Again, A is updated with P+A.

In step 480, the method 400 queries whether there are any mismatch errors remaining that have not been reordered. If the query is positively answered, method returns to step 420, where steps 420-470 are repeated. If the query is negatively answered, then method 400 ends in step 485.

FIG. 3 depicts an illustrative new order or a permutation of the natural order in applying the method 400. Namely, a number or an index associated with the error N₁ is preceded by a plurality of P₁₋₃ indexes which, in turn, is followed by an index N₂ which is preceded by a plurality of P₄₋₅ indexes and so on until all the indexes in the natural order have been reordered into a new ordered sequence.

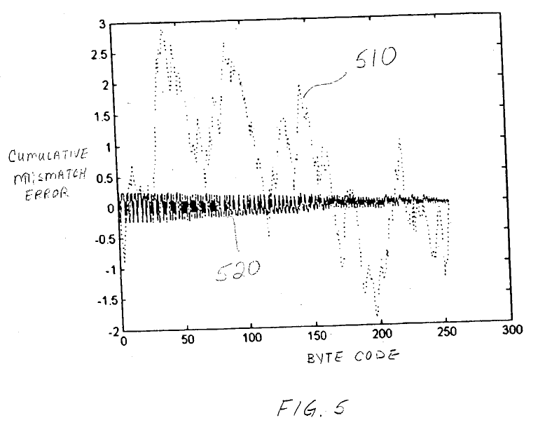

FIG. 5 depicts a graph 500 illustrating the cumulative sum of the random mismatch errors plotted against each DAC code or byte code. The dotted line 510 illustrates the cumulative sum errors of a natural order, whereas the continuous line 520 illustrates the cumulative sum errors of a new order or a permuted sequence as described above. The graph illustrates the INL value of the permuted sequence did not exceed 0.3, while the natural order could be 16 times larger.

FIG. 5 clearly illustrates that the cumulative sum of the mismatch errors for the arbitrary ordering or natural order of the current source array is not optimum. In fact there are codes where the mismatch errors accumulate undesirably and become quite large. The present invention is an efficient method of determining a switching order such that given a known distribution of mismatch errors, the cumulated error is minimized at each DAC code. It is clear that the above method can be employed to reduce INL error provided that full permutation of thermometer coded transistors is applied and that individual transistors errors are known. While this approach is implemented only after all transistor currents are measured and the DAC is manufactured, the present approach can be deployed to minimize the effect of known systematic errors. In fact, the present invention has full flexibility to be adopted to the actual floorplan of the current source array layout and will provide better reduction of the systematic errors as shown below.

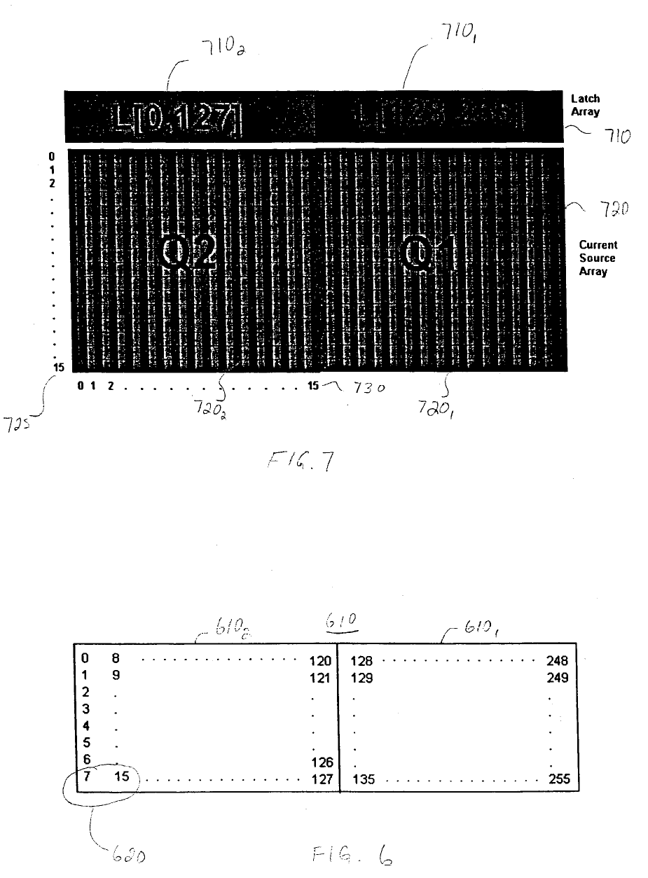

After the permuted order is determined from the method 400 of FIG. 4, it can be implemented in the layout of the DAC. FIG. 6 depicts an embodiment of an order of a latch 610 capable of use with the present invention. Latch 610 comprises latch portions 610₁ and 610₂. Maintaining the example as provided above, latch 610 is used in conjunction with an 8 bit current source array. Thus, there are 2^{N} (i.e. 2⁸=256) distinct signals that need to be properly routed, where N is the number of bits addressing the thermometer decoder which controls the unary current source array. The binary weighted current sources are necessarily switched in an ordered manner. There are two large blocks of repetitive structures (the latch array and the unary current source array) in a DAC, that need to be connected in the pseudo-random fashion. The latches are assigned one order based on their location in their array as shown in FIG. 6. The counting order can be along columns or rows. In FIG. 6, the order is along the columns.

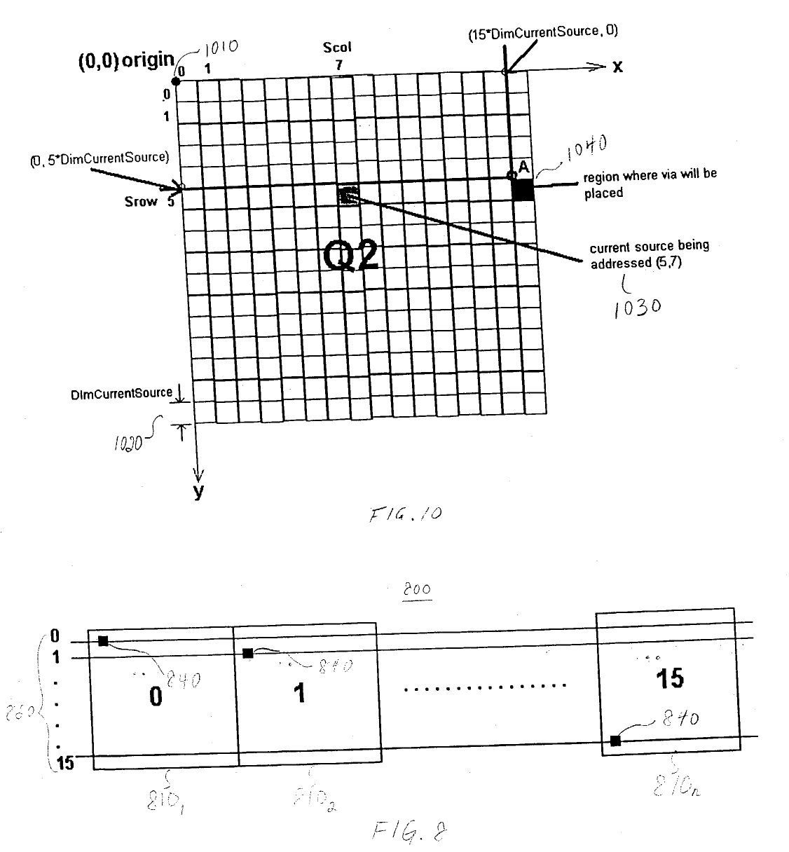

FIG. 7 depicts an illustrative embodiment of a DAC capable of using the above-order method in the manufacturing and/or calibration of the DAC. FIG. 7 depicts a DAC comprising a latch array 710 and a current source array 720.

Current source array 720 comprises a plurality of quadrants. For simplicity, FIG. 7 depicts quadrants Q1 720₁ and quadrants Q2 720₂. Each respective quadrant contains columns 725 and rows 730. As described below, columns 725 and rows 730 define cross sectional locations for wiring to latches thru the use of “vias”.

In one illustrative embodiment, the 2^{N} current sources numbered S[0,2^{N}−1] are arranged in a square array with dimension 2^{N/2} (e.g. 16×16). Every current source is split into four (4) symmetrical locations (not shown). An illustrative method of constructing the entire current source array is to flip the 16×16 current source array over a vertical axis drawn along its right edge, and then flip the two adjacent arrays along a horizontal axis drawn along their common bottom edge. The resulting structure is square with dimension 2^{(N/2)+1} (e.g. 32×32). In the example of FIG. 7, quadrant Q2 720₂ is the original quadrant that gives rise to the other quadrants by flipping.

Latch array 710 also comprises two sections (710₁ and 710₂) connected to current source array quadrants 720₁ and 720₂ respectively. For illustrative purposes only, a latch array having the same width as the current source array is used to make the layout more uniform. However, a person skilled in the art will appreciate that the latch array may be implemented with other widths and lengths. Therefore, 2^{N-1} (e.g. 128) latches numbered L[0,2^{N-1}−1] (i.e. L[0,127]) will be aligned over Q2 while the other 2^{N-1} latches numbered L[2^{N-1},2^{N}−1] (i.e. L[128,255]) will be aligned over quadrant Q1. Furthermore, latches over Q2 are directly wired to current sources in Q2. By directly wired, it is meant that each latch is connected to one vertical wire going to a current source in the quadrant directly below it. Each directly wired current source is connected to its symmetric counterparts in the other three quadrants. Similarly, latches over Q1 are directly wired to current sources in Q1. Since Q1 is a flipped image of Q2, the routing area above each current source is divided in half vertically to differentiate which set of latches L[0:127] or L[128:255] will handle its switching as shown in FIG. 7. FIG. 7 also shows how the current sources are addressed with a row and column number. In the via placement algorithm as disclosed below, the row and column index of each current source are called Srow and Scol, respectively. Srow and Scol are in the range [0,2^{N/2}−1] (i.e. [0,15]).

Layers of metal directly above the arrays are used to construct a dense routing grid. The routing grid's horizontal wires are in one metal layer (e.g. metal3), and all vertical wires are in a different metal layer (e.g. metal4).

Specifically, FIG. 8 depicts an embodiment of a portion 800 of a current source array Q2 720₂ used in accordance with the invention. Portion 800 depicts a plurality of current sources 810₁₋ₙ within a row of the current source array 720. Within a row, 16 horizontal wires 820 in metal3 and 16 vertical wires (not shown in FIG. 8) in metal4 are used to address 16 current sources 810₁₋ₙ. Specifically, vias 840 are placed in a regular manner from the 16 metal3 wires to a contact local to a current source as shown in FIG. 8, i.e., current source 810₁ can be accessed by placing a via anywhere along horizontal wire “0” 820. Since the metal4 vertical wires extend over the entire current source array, any latch can be connected to any current source by placing a via at the proper metal3-metal4 grid junction. It should be noted that the vias placed at the metal3-metal4 grid junction is not the vias 840 as shown in FIG. 8. For simplicity, it is assumed that the current source array is uniform and the spaces between the routing wires over the array are all equal.

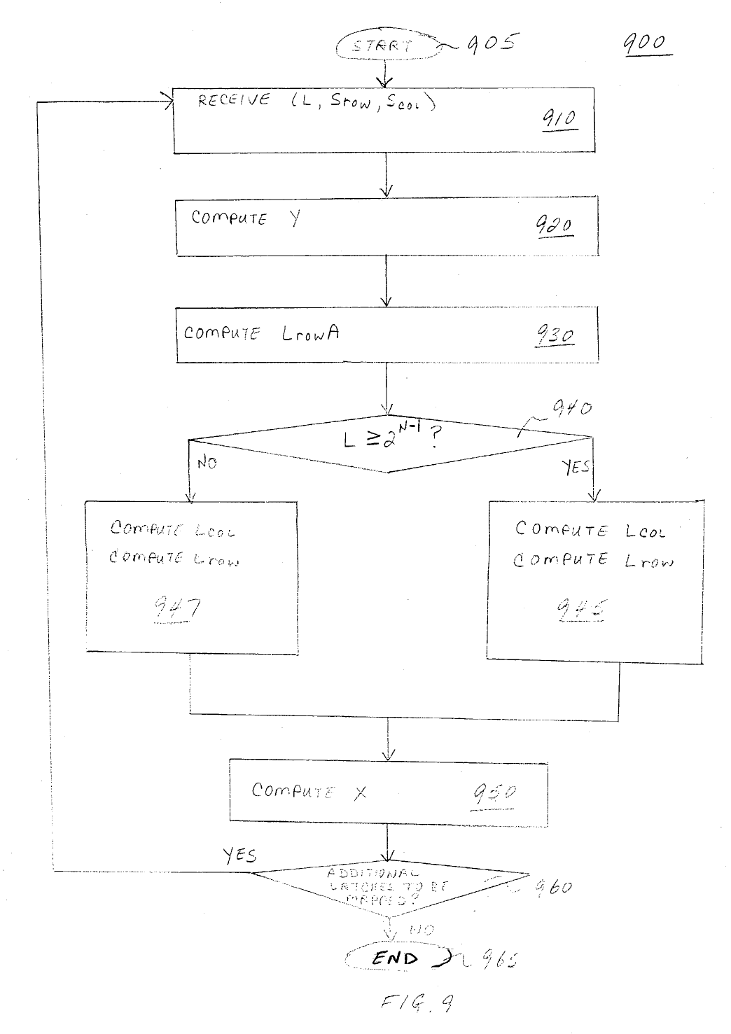

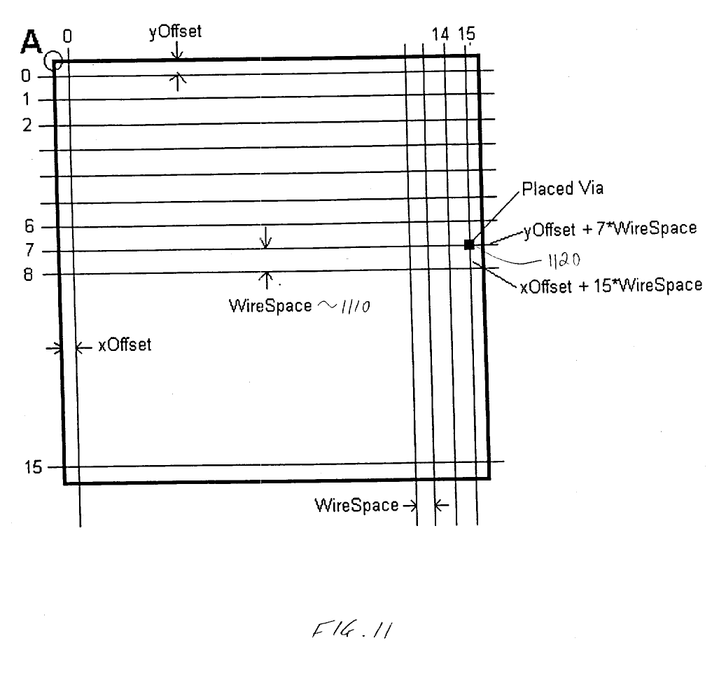

FIG. 9 depicts a flowchart for placing vias to accomplish the mapping of all latches (e.g., in the fixed order as shown in FIG. 6) to the current sources (e.g., in Q2 of FIG. 7). FIG. 10 illustrates a quadrant of the current source array and FIG. 11 illustrates a current source within the quadrant. The reader is encouraged to refer to FIGS. 9-11 collectively to better understand the description of the method for mapping the latches to the current sources.

The method 900 begins at step 905 and proceeds to step 910. In step 910, the method acquires an ordered triple (L, Srow, Scol), generated from the method depicted in FIG. 4, indicating the connection sequence between a latch L[0,2^{N}−1] 710₂ and a current source defined by Srow[0,2^{N/2}−1] and Scol[0,2^{N/2}−1], where each connection is called a “via”.

In step 920, method 900 computes y. The following parameters are defined prior to the computation of y:

Let (x,y) be the coordinates where the via will be placed.

Let the origin, i.e. via coordinate (0,0) 1010, be at the upper left corner of Q2 as shown in FIG. 10.

Let the number of latches per column be called LatchesPerCol, e.g., 8 in this example as shown in FIG. 6.

Let Lrow[0,LatchesPercol−1] be an index representing which row contains latch L as shown in FIG. 6.

Let Lcol[0,2^{N/2}−2] be an index representing which column contains latch L as shown in FIG. 6.

Let DimCurrentSource be the dimension of a square current source 1020 as shown in FIG. 10.

Let WireSpace be the center-to-center distance between adjacent grid intersections 1110 as shown in FIG. 11.

Specifically, y is computed in accordance with the following formula:

y=(Srow*DimCurrentSource)+(Scol* WireSpace)+yOffset (Equ. 1)

In step 930, method 900 computes LrowA. Specifically, LrowA is computed in accordance with:

LrowA=L modulo LatchesPerCol (Equ. 2)

In step 940, the method 900 queries whether L is greater than or equal to 2^{N-1}. If the query is positively answered, method 900 proceeds to step 945. If the query is negatively answered, method 900 proceeds to step 947.

In step 945, Lcol and Lrow are computed. Specifically, Lcol and Lrow are computed in accordance with:

Lcol=(2^{N/2+1}−1)−(the quotient when L is divided by LatchesPerCol) (Equ. 3)

Lrow=(2*LatchesPerCol−1)−LrowA (Equ. 4)

In step 945, Lcol and Lrow are computed. Specifically, Lcol and Lrow are computed in accordance with:

Lcol=the quotient when L is divided by LatchesPerCol (Equ. 5)

Lrow=LrowA (Equ. 6)

In step 950, method 900 computes x. Specifically, x is computed in accordance with:

x=(Lcol*DimCurrentSource)+(Lrow*WireSpace)+xOffset (Equ. 7)

In step 960, method 900 queries whether additional latches need to be mapped. If the query is positively answered, then method 900 returns to step 910, where steps 910-950 are repeated. If the query is negatively answered, then method 900 ends in step 965.

An example is now described in implementing method 900 of FIG. 9. For example, according to the sequencing method of FIG. 4, an ordered triple (128, 5, 7) is received that defines the connection between latch array 710 and current source array 720. Specifically, a current source (5,7) is being addressed within the current source array. In order to determine the placement of a via, the coordinates (x,y) defining the placement of the via is computed as follows:

Let (L, Srow, Scol) be (128,5,7), then

y=(5*DimCurrentSource)+(7*WireSpace)+yOffset

LrowA=128 modulo 8=0

Lcol=31−16=15

Lrow(2*8−1)−0=15

x=(15*DimCurrentSource)+(15*WireSpace)+xOffset

Thus, the via is placed at location 1120 as illustrated in FIG. 11.

FIG. 11 shows that within current source (5,15) the via is placed on intersection coordinates (7,15). Within the intersection coordinates (7,15), the coordinate with value 7 uniquely identifies which current source within the row of 16 current sources is being selected. The coordinate paired with the 7, in this case with value 15 (as shown in FIG. 6 as 620), uniquely identifies which latch is being connected to the selected current source. This via falls within the region in 720₁ of FIG. 7 indicating that current source (5,7) is connected to a latch that is within the set L[128,255] 710₁. Latches are uniformly routed according to the order shown in FIG. 6. By following this via placement algorithm, the vias only need to be placed in Q2 and flipped in a symmetrical fashion to create the other three quadrants.

It should be noted that over each row of current sources, there are 16 horizontal wires, where each wire is coupled to one of the current sources in that row. For example, the topmost wire is connected to the leftmost current source. The bottommost wire is connected to the rightmost current source as shown in FIG. 8. Thus, there is a horizontal wire corresponding to the current source at Scol=7 in a particular row that extends throughout the entire row. The proper vertical wire to connect to this horizontal wire is dictated by latch to current source mapping. Since latch numbers correspond to a fixed latch location (FIG. 6), the vertical wire is first constrained to be over switch column (Scol) 15. Within that routing column, there is a multitude of vertical wires connected to unique latches within the latch column. The 15 in the intersection coordinates corresponds to the correct latch within the latch column. Thus, to address the current source (5,7) 1030, a via is actually placed at position 1040 as shown in FIG. 10.

It should be noted that random errors are not known prior to fabrication of the DAC and these errors can be different for each DAC fabricated even if the design is identical. However, it is possible to employ circuitry in the DAC to measure these random mismatch errors or to measure these errors at wafer probe and then use the present invention to calibrate out these random errors. Thus, the present invention can be employed to create a self calibrating DAC.

In the case of systematic mismatch errors (non random), it is possible to estimate these errors or to derive the error distribution from test silicon. The present invention can then be used to program into the design, prior to fabrication, the optimum switching order for the suppression of these systematic errors.

It should be noted that although the present invention is described in the context of a current source array, those skilled in the art will realize that the present invention can be adapted to a voltage source array as well. In fact, the present approach can be applied to an array of passive elements such as resistors and capacitors. Additionally, it is contemplated that the term systematic error may also encompass the accumulated effect of errors attributed to delays.

It should be noted that the present invention may be implemented using a general purpose computer (e.g., a processor (CPU) with a memory) in conjunction with various input and output devices, e.g., a storage device, e.g., a disk drive and an optical drive, a keyboard, a display and the like. Thus, it should be understood that the steps as described above may be implemented as one or more physical devices that are coupled to the processor through a communication channel. Alternatively, some of these steps may be represented by one or more software applications (or even a combination of software and hardware, e.g., using application specific integrated circuits (ASIC)), where the software is loaded from a storage medium, (e.g., a magnetic or optical drive or diskette) and operated by the CPU in the memory of the computer. As such, the methods (including associated steps and data structures) of the present invention can be stored on a computer readable medium, e.g., RAM memory, magnetic or optical drive or diskette and the like.

Although various embodiments which incorporate the teachings of the present invention have been shown and described in detail herein, those skilled in the art can readily devise many other varied embodiments that still incorporate these teachings.

What is claimed is:

1. A method for determining a switching order for an array of elements, said method comprising the steps of:
a) obtaining systematic error for each of the elements within the array;
b) setting a desired accumulated systematic error value (A);
c) setting a desired value (D);
d) selecting an element (N) where a magnitude of the systematic error of said selected element is largest;
e) selecting an element (P) having a systematic error magnitude that will minimize an absolute value of said systematic error magnitude of element P plus a difference between said desired accumulated systematic error value (A) and said desired value (D);
f) placing an index representative of element P as a preceding element before an index representative of said element N in a ordered sequence;
g) repeating steps e) and f) until no remaining elements can satisfy the requirement of further minimizing an absolute value of said selected systematic error magnitude of elements P plus said difference between said desired accumulated systematic error value (A) and said desired value (D);
h) placing said index representative of said element N in said ordered sequence;
i) selecting a next element (N) where a magnitude of the systematic error of said next selected element is next largest among the elements yet to be ordered; and
j) repeating steps d) to i) until indexes for all of the elements have been placed into said ordered sequence.

2. The method of claim 1, wherein said desired accumulated systematic error value (A) is equal to zero.

3. The method of claim 1, wherein said desired value (D) is equal to −N/2.

4. The method of claim 1 further comprising the step of:
k) applying said ordered sequence for addressing said array of elements.

5. The method of claim 4, wherein said ordered sequence is applied to map a latch array to said array of elements.

6. The method of claim 1, wherein said array of elements is an array of current sources.

7. The method of claim 1, wherein said array of elements is an array of voltage sources.

8. The method of claim 1, wherein said array of elements is an array of passive elements.

9. The method of claim 1, wherein said passive elements comprise resistors.

10. The method of claim 1, wherein said passive elements comprise capacitors.

11. A digital to analog converter (DAC), comprising:
an element array layer comprising a plurality of elements;
a switching latch array layer comprising a plurality of latches;
a first set of plurality of wires disposed along a row of said plurality of elements;
a second set of plurality of wires disposed along a column of said plurality of elements, and
a plurality of vias coupled to said first set and second set of plurality of wires for allowing said plurality of latches to address said plurality of elements in an ordered sequence.

12. The apparatus of claim 11, wherein said elements are current sources.

13. The apparatus of claim 11, wherein said elements are voltage sources.

14. The apparatus of claim 11, wherein said elements are resistors.

15. The apparatus of claim 11, wherein said elements are capacitors.

16. The apparatus of claim 11, wherein said first set of plurality of wires are disposed horizontally along said row of said plurality of elements and said second set of plurality of wires are disposed vertically along said column of said plurality of elements.

17. The apparatus of claim 11, wherein said first set of plurality of wires are disposed vertically along said row of said plurality of elements and said second set of plurality of wires are disposed horizontally along said column of said plurality of elements.

18. The apparatus of claim 11, wherein said first set of plurality of wires are disposed along said row of said plurality of elements such that a plurality of said wires are disposed over each of the said elements.

19. The apparatus of claim 11, wherein said second set of plurality of wires are disposed along said column of said plurality of elements such that a plurality of said wires are disposed over each of the said elements.

20. A computer-readable medium having stored thereon a plurality of instructions, the plurality of instructions including instructions which, when executed by a processor, cause the processor to perform the steps comprising of:
a) obtaining systematic error for each of the elements within the array;
b) setting a desired accumulated systematic error value (A);
c) setting a desired value (D);
d) selecting an element (N) where a magnitude of the systematic error of said selected element is largest;
e) selecting an element (P) having a systematic error magnitude that will minimize an absolute value of said systematic error magnitude of element P plus a difference between said desired accumulated systematic error value (A) and said desired value (D);
f) placing an index representative of element P as a preceding element before an index representative of said element N in a ordered sequence;
g) repeating steps e) and f) until no remaining elements can satisfy the requirement of further minimizing an absolute value of said selected systematic error magnitude of elements P plus said difference between said desired accumulated systematic error value (A) and said desired value (D);
h) placing said index representative of said element N in said ordered sequence;
i) selecting a next element (N) where a magnitude of the systematic error of said next selected element is next largest among the elements yet to be ordered; and
j) repeating steps d) to i) until indexes for all of the elements have been placed into said ordered sequence.

21. A method for determining a switching order for an array of elements, said method comprising the steps of:
a) obtaining systematic error for each of the elements within the array;
b) setting a desired accumulated systematic error value (A);
c) setting a desired value (D);
d) selecting an element (N) where a magnitude of the systematic error of said selected element is largest;
e) selecting an element (P) having a systematic error magnitude that will minimize an absolute value of (P+A−D);
f) placing an index representative of element P as a preceding element before an index representative of said element N in a ordered sequence;
g) updating said desired accumulated systematic error value (A);
h) repeating steps e) and g) until no remaining elements can satisfy the requirement of further minimizing said absolute value of (P+A−D);
i) placing said index representative of said element N in said ordered sequence;
j) selecting a next element (N) where a magnitude of the systematic error of said next selected element is next largest among the elements yet to be ordered; and
k) repeating steps d) to j) until indexes for all of the elements have been placed into said ordered sequence.

22. Method for mapping a latch array having a plurality of latches to an element array having a plurality of elements, said method comprising the steps of:
a) receiving an input specifying an element within said element array to be addressed and one of said latches of said latch array to address said element; and
b) determining an intersection of two wires represented by coordinates (x,y) for placing a via that will allow said latch to address said element.

23. The method of claim 22, further comprising the step of:
c) placing said via between said two wires.

24. The method of claim 22, wherein said latch array and said element array are deployed within a digital-to-analog converter.

25. The method of claim 24, wherein said elements of said element array are current sources, voltage sources or passive elements.

26. A computer-readable medium having stored thereon a plurality of instructions, the plurality of instructions including instructions which, when executed by a processor, cause the processor to perform the steps comprising of:
a) receiving an input specifying an element within said element array to be addressed and one of said latches of said latch array to address said element; and
b) determining an intersection of two wires represented by coordinates (x,y) for placing a via that will allow said latch to address said element.
